(19) United States
(12) Patent Application Publication
(10) Pub. No.: US 2026/0144166 A1
(43) Pub. Date: May 21, 2026

(54) PACKAGE COMPRISING AN INTEGRATED DEVICE, A METALLIZATION PORTION AND AN OFFSET MEMORY DEVICE

(71) Applicant: QUALCOMM Incorporated, San Diego, CA (US)

(72) Inventors: Aniket PATIL, San Diego, CA (US); Manuel ALDRETE, Encinitas, CA (US); Zhijie WANG, San Diego, CA (US)

(21) Appl. No.: 18/949,873

(22) Filed: Nov. 15, 2024

(51) Int. Cl. H01L 23/498; H01L 21/48; H01L 23/00; H01L 23/31; H01L 23/373; H01L 23/538; H01L 25/03

(52) U.S. Cl. CPC H10W 90/701; H10W 40/25; H10W 70/611; H10W 90/401; H10W 70/093; H10W 72/07354; H10W 72/347; H10W 74/141; H10W 74/15; H10W 90/00; H10W 90/724; H10W 90/734

(57) ABSTRACT

A package comprising a substrate; an integrated device coupled to the substrate; a metallization portion coupled to a back side of the integrated device; a plurality of wire bonds coupled to the substrate and the metallization portion; and an encapsulation layer coupled to the metallization portion and the substrate, wherein the encapsulation layer at least partially encapsulates the integrated device and the plurality of wire bonds.

### Field

Various features relate to packages with substrates and integrated devices.

### BACKGROUND

A package may include a substrate and integrated devices. These components are coupled together to provide a package that may perform various electrical functions. There is an ongoing need to provide better performing packages. Moreover, there is also an ongoing need to reduce and/or minimize the overall size of the packages.

### SUMMARY

Various features relate to packages with substrates and integrated devices.

One example provides a package comprising a substrate; an integrated device coupled to the substrate; a metallization portion coupled to a back side of the integrated device; a plurality of wire bonds coupled to the substrate and the metallization portion; and an encapsulation layer coupled to the metallization portion and the substrate, wherein the encapsulation layer at least partially encapsulates the integrated device and the plurality of wire bonds.

Another example provides a method for fabricating a package. The method provides a substrate. The method forms and couple a plurality of wire bonds to the substrate. The method couples an integrated device to the substrate. The method forms an encapsulation layer that is coupled to the substrate, the integrated device and the plurality of wire bonds. The method forms a metallization portion that is coupled to the encapsulation layer and the plurality of wire bonds.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a substrate, a metallization portion and a plurality of wire bonds.

FIG. 2 illustrates an exemplary cross sectional profile view of a package that includes a substrate, a metallization portion and a plurality of wire bonds.

FIG. 3 illustrates an exemplary cross sectional profile view of a package that includes a substrate, a metallization portion and a plurality of wire bonds.

FIGS. 4A-4E illustrate an exemplary sequence for fabricating a package that includes a substrate, an integrated device, a metallization portion and a plurality of wire bonds.

FIGS. 5A-5E illustrate an exemplary sequence for fabricating a package that includes a substrate, an integrated device, a metallization portion and a plurality of wire bonds.

FIG. 6 illustrates an exemplary flow chart of a method for fabricating a package that includes a substrate, an integrated device, a metallization portion and a plurality of wire bonds.

FIGS. 7A-7B illustrate an exemplary sequence for fabricating a metallization portion.

FIG. 8 illustrates an exemplary flow chart of a method for fabricating a metallization portion.

FIG. 9 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a substrate; an integrated device coupled to the substrate; a metallization portion coupled to a back side of the integrated device; a plurality of wire bonds coupled to the substrate and the metallization portion; and an encapsulation layer coupled to the metallization portion and the substrate, wherein the encapsulation layer at least partially encapsulates the integrated device and the plurality of wire bonds. The package may have improved thermal performance due to the relative position and/or relative location of the various components of the package. All of the above advantages are provided while also providing a more compact form factor for the package.

### Exemplary Package Comprising Wire Bonds and an Integrated Device

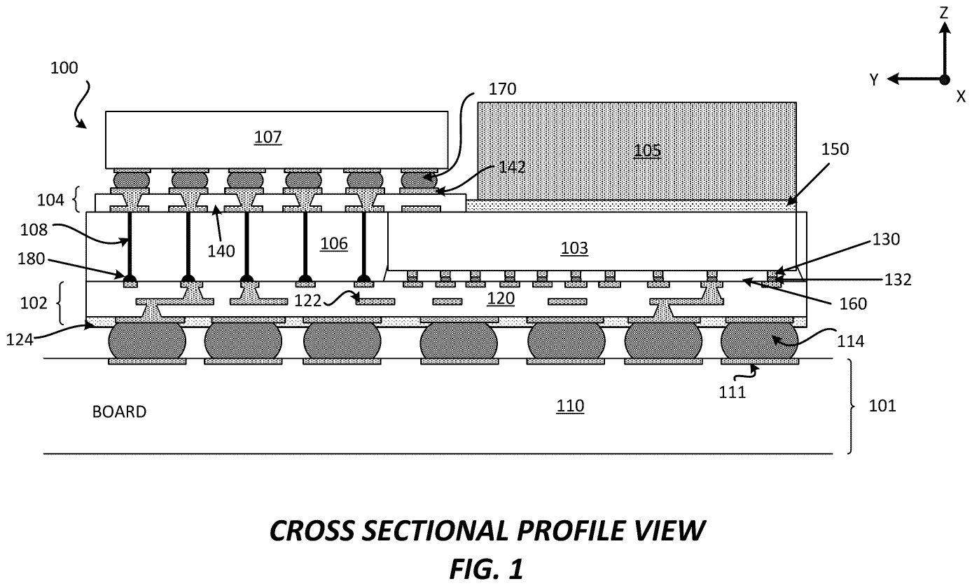

FIG. 1 illustrates a cross sectional profile view of a package 100 that includes a plurality of wire bonds. The package 100 may be a package on package (PoP). The package 100 is coupled to a board 101 through a plurality of solder interconnects 114. The board 101 includes at least one board dielectric layer 110 and a plurality of board interconnects 112. The board 101 may include a printed circuit board (PCB). In some implementations, the package 100 may be coupled to a substrate instead of the board 101.

The package 100 includes a substrate 102, a metallization portion 104, an integrated device 103, a plurality of wire bonds 108 and an encapsulation layer 106. The metallization portion 104 includes at least one dielectric layer 140, a plurality of metallization interconnects 142. In some implementations, the dielectric layer 140 may include prepreg and/or polyimide. The substrate 102 may be a laminated substrate (e.g., coreless substrate, cored substrate). The substrate 102 may include a dielectric layer 120 (e.g., substrate dielectric layer), a plurality of interconnects 122 (e.g., substrate interconnects) and a solder resist layer 124. In some implementations, the dielectric layer 120 may include prepreg and/or polyimide.

The integrated device 103 is coupled to the substrate 102. The integrated device 103 may be coupled to the plurality of interconnects 122 through a plurality of pillar interconnects 130 and/or a plurality of solder interconnects 132. An underfill 160 may be located vertically between the integrated device 103 and the substrate 102. The underfill 160 may at least partially surround the plurality of pillar interconnects 130 and/or the plurality of solder interconnects 132. The integrated device 103 may be coupled to and touch the metallization portion 104. The back side of the integrated device 103 may be coupled to the plurality of metallization interconnects 142 of the metallization portion 104.

The encapsulation layer 106 is coupled to the metallization portion 104, the substrate 102 and the integrated device 103. The encapsulation layer 106 may at least partially encapsulate the integrated device 103, the plurality of wire bonds 108 and the underfill 160. Thus, the integrated device 103 and the plurality of wire bonds 108 may be located at least partially in the encapsulation layer 106. The encapsulation layer 106 may include a mold, a resin, an epoxy and/or a filler. The encapsulation layer 106 may be located between the metallization portion 104 and the substrate 102. The substrate 102 and the plurality of wire bonds 108 may be located laterally to the integrated device 103. The encapsulation layer 106 may be located vertically between the metallization portion 104 and the substrate 102. The encapsulation layer 106 may include a different material from the underfill 160. The underfill may 160 may include a different material from the encapsulation layer 106.

The plurality of wire bonds 108 are coupled to the substrate 102 and the metallization portion 104. The plurality of wire bonds 108 may be coupled to and touch (i) the plurality of metallization interconnects 142 of the metallization portion 104 and (ii) the plurality of interconnects 122 of the substrate 102. The plurality of wire bonds 108 may include a plurality of ball bonds 180. The plurality of ball bonds 180 may be considered part of the plurality of wire bonds 108. The plurality of ball bonds 180 of the plurality of wire bonds 108, may be coupled to and touch the plurality of interconnects 122 of the substrate 102.

The metallization portion 104 is coupled to and touch (i) the encapsulation layer 106, (ii) the plurality of wire bonds 108 and (iii) the back side of the integrated device 103. The plurality of metallization interconnects 142 may be coupled to and touch the plurality of wire bonds 108. The metallization portion 104 may include a redistribution portion. The plurality of metallization interconnects 142 may include a plurality of redistribution interconnects. A redistribution interconnect may include portions that have a U-shape or V-shape. The terms “U-shape” and” V-shape” shall be interchangeable. The terms “U-shape” and “V-shape” may refer to the side profile shape of the interconnects, metallization interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). In some implementations, a process for fabricating redistribution interconnects may form the U-shape interconnect (or the V-shape interconnect).

In some implementations, a difference between the substrate 102 and the metallization portion 104 may be that the metallization portion 104 includes metallization interconnects that have different line and spacing (L/S) or different width and spacing from the interconnects of the substrate 102. For example, the metallization interconnects from the metallization portion 104 may have width and spacing that are less than the width and spacing of the interconnects of the substrate 102.

The heat sink 105 is coupled to a back side of the integrated device 103 through a thermal interface material (TIM) 150. In some implementations, instead of or in addition to a thermal interface material, an adhesive may be used to couple the heat sink 105 to the back side of the integrated device 103. The back side of the integrated device 103 may be a side of the integrated device 103 that includes a die substrate (e.g., silicon die substrate). The heat sink 105 may include a metal. In some implementations, the heat sink 105 may be a metal block.

An integrated device 107 may be coupled to the metallization portion 104 through a plurality of solder interconnects 170. The plurality of solder interconnects 170 may be coupled to and touch the plurality of metallization interconnects 142 and interconnects of the integrated device 107. The integrated device 107 may be an memory integrated device. In some implementations, the integrated device 107 may be a package. In some implementations, the integrated device 107 may be a memory package. The integrated device 107 may be offset (e.g., horizontally offset) from the integrated device 103. The integrated device 107 may or may not vertically overlap with a portion of the integrated device 103. At least a portion of the integrated device 107 is located laterally to the heat sink 105. The integrated device 107 and/or the heat sink 105 may considered part of the package 100.

An electrical path between the integrated device 107 and the integrated device 103 may include (i) the plurality of solder interconnects 170, (ii) the metallization portion 104, (iii) the plurality of wire bonds 108, (iv) the substrate 102, (v) the plurality of solder interconnects 132 and/or the plurality of pillar interconnects 130. For example, an electrical path between the integrated device 107 and the integrated device 103 may include (i) at least one solder interconnect from the plurality of solder interconnects 170, (ii) at least one metallization interconnect from the plurality of metallization interconnects 142, (iii) at least one wire bond from the plurality of wire bonds 108, (iv) at least one interconnect from the plurality of interconnects 122, (v) at least one solder interconnect from the plurality of solder interconnects 132 and/or (vi) at least one pillar interconnect from the plurality of pillar interconnects 130.

The configuration of the package 100 provides a package with improved heat dissipation and/or thermal performance, which helps improve the performance (e.g., thermal performance) of the package 100. This is possible because the metallization portion 104 and/or the integrated device 107 is/are offset (e.g., horizontally offset) from the integrated device 103 and does not cover the back side of the integrated device 103. In some implementations, the use of the plurality of wire bonds 108 helps provide high aspect ratio interconnects that can extend through the encapsulation layer 106, and may be useful for the integrated device 103 with high thicknesses.

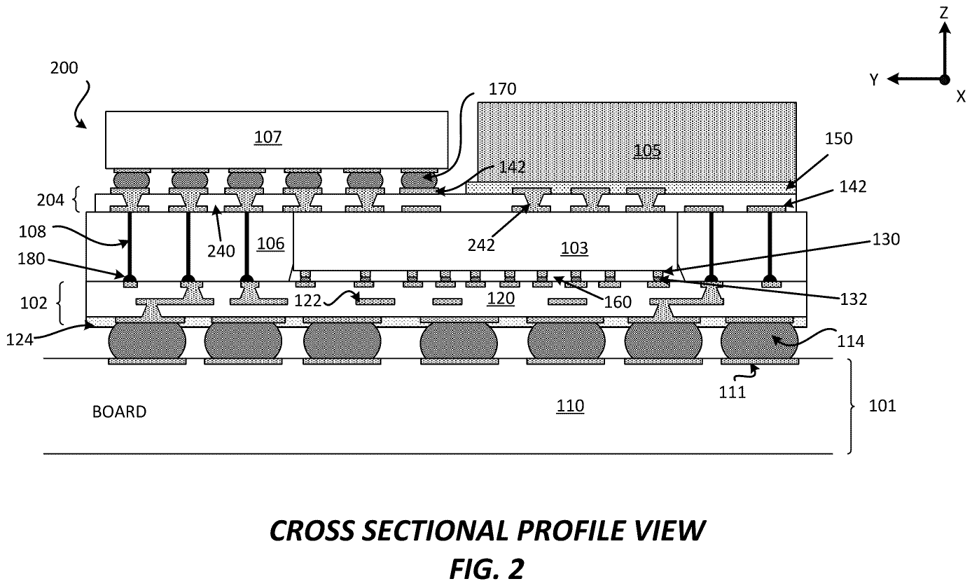

FIG. 2 illustrates a cross sectional profile view of a package 200 that includes a plurality of wire bonds. The package 200 is similar to the package 100 of FIG. 1, and may include similar components that are arranged in a similar manner. The package 200 may be a package on package (PoP). The package 200 is coupled to a board 101 through a plurality of solder interconnects 114. The board 101 includes at least one board dielectric layer 110 and a plurality of board interconnects 112. The board 101 may include a printed circuit board (PCB). In some implementations, the package 100 may be coupled to a substrate instead of the board 101.

The package 200 includes a substrate 102, a metallization portion 204, an integrated device 103, a plurality of wire bonds 108 and an encapsulation layer 106. The metallization portion 204 includes at least one dielectric layer 140, a plurality of metallization interconnects 142 and a plurality of metallization interconnects 242. In some implementations, the dielectric layer 140 may include prepreg and/or polyimide. The substrate 102 may be a laminated substrate (e.g., coreless substrate, cored substrate). The substrate 102 may include a dielectric layer 120 (e.g., substrate dielectric layer), a plurality of interconnects 122 (e.g., substrate interconnects) and a solder resist layer 124. In some implementations, the dielectric layer 120 may include prepreg and/or polyimide.

The integrated device 103 is coupled to the substrate 102. The integrated device 103 may be coupled to the plurality of interconnects 122 through a plurality of pillar interconnects 130 and/or a plurality of solder interconnects 132. An underfill 160 may be located vertically between the integrated device 103 and the substrate 102. The underfill 160 may at least partially surround the plurality of pillar interconnects 130 and/or the plurality of solder interconnects 132. The integrated device 103 may be coupled to and touch the metallization portion 204. The back side of the integrated device 103 may be coupled to the metallization portion 204 (e.g., coupled to the plurality of metallization interconnects 142 of the metallization portion 204).

The encapsulation layer 106 is coupled to the metallization portion 204, the substrate 102 and the integrated device 103. The encapsulation layer 106 may at least partially encapsulate the integrated device 103, the plurality of wire bonds 108 and the underfill 160. Thus, the integrated device 103 and the plurality of wire bonds 108 may be located at least partially in the encapsulation layer 106. The encapsulation layer 106 may include a mold, a resin, an epoxy and/or a filler. The encapsulation layer 106 may be located between the metallization portion 204 and the substrate 102. The substrate 102 and the plurality of wire bonds 108 may be located laterally to the integrated device 103. The encapsulation layer 106 may be located vertically between the metallization portion 204 and the substrate 102.

The plurality of wire bonds 108 are coupled to the substrate 102 and the metallization portion 204. The plurality of wire bonds 108 may be coupled to and touch (i) the plurality of metallization interconnects 142 of the metallization portion 204 and (ii) the plurality of interconnects 122 of the substrate 102. The plurality of wire bonds 108 may include a plurality of ball bonds 180. The plurality of ball bonds 180 may be considered part of the plurality of wire bonds 108. The plurality of ball bonds 180 of the plurality of wire bonds 108, may be coupled to and touch the plurality of interconnects 122 of the substrate 102.

The metallization portion 204 is coupled to and touch (i) the encapsulation layer 106, (ii) the plurality of wire bonds 108 and (iii) the back side of the integrated device 103. The plurality of metallization interconnects 142 may be coupled to and touch the plurality of wire bonds 108. The plurality of metallization interconnects 242 may be coupled to and touch the back side of the integrated device 103. For example, the plurality of metallization interconnects 242 may touch the die substrate of the integrated device 103. The plurality of metallization interconnects 242 may be configured as heat sink interconnects. The plurality of metallization interconnects 242, which may be configured as one or more heat sinks, may be configured to be free of any electrical connection with other components in the package 200. That is, for example, the plurality of metallization interconnects 242 may not be electrically coupled to other components, such as the integrated device 103.

The metallization portion 204 may include a redistribution portion. The plurality of metallization interconnects 142 may include a plurality of redistribution interconnects. A redistribution interconnect may include portions that have a U-shape or V-shape. The terms “U-shape” and” V-shape” shall be interchangeable. The terms “U-shape” and “V-shape” may refer to the side profile shape of the interconnects, metallization interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). In some implementations, a process for fabricating redistribution interconnects may form the U-shape interconnect (or the V-shape interconnect).

In some implementations, a difference between the substrate 102 and the metallization portion 204 may be that the metallization portion 204 includes metallization interconnects that have different line and spacing (L/S) or different width and spacing from the interconnects of the substrate 102. For example, the metallization interconnects from the metallization portion 204 may have width and spacing that are less than the width and spacing of the interconnects of the substrate 102.

The heat sink 105 is coupled to a metallization portion 204 through a thermal interface material (TIM) 150. In some implementations, instead of or in addition to a thermal interface material, an adhesive may be used to couple the heat sink 105 to the metallization portion 204.

An integrated device 107 may be coupled to the metallization portion 204 through a plurality of solder interconnects 170. The plurality of solder interconnects 170 may be coupled to and touch the plurality of metallization interconnects 142 and interconnects of the integrated device 107. The integrated device 107 may be an memory integrated device. In some implementations, the integrated device 107 may be a package. In some implementations, the integrated device 107 may be a memory package. The integrated device 107 may be offset (e.g., horizontally offset) from the integrated device 103. The integrated device 107 may or may not vertically overlap with a portion of the integrated device 103. At least a portion of the integrated device 107 is located laterally to the heat sink 105. The integrated device 107 and/or the heat sink 105 may considered part of the package 200.

An electrical path between the integrated device 107 and the integrated device 103 may include (i) the plurality of solder interconnects 170, (ii) the metallization portion 204, (iii) the plurality of wire bonds 108, (iv) the substrate 102, (v) the plurality of solder interconnects 132 and/or the plurality of pillar interconnects 130. For example, an electrical path between the integrated device 107 and the integrated device 107 may include (i) at least one solder interconnect from the plurality of solder interconnects 170, (ii) at least one metallization interconnect from the plurality of metallization interconnects 142, (iii) at least one wire bond from the plurality of wire bonds 108, (iv) at least one interconnect from the plurality of interconnects 122, (v) at least one solder interconnect from the plurality of solder interconnects 132 and/or (vi) at least one pillar interconnect from the plurality of pillar interconnects 130.

The configuration of the package 200 provides a package with improved heat dissipation and/or thermal performance, which helps improve the performance (e.g., thermal performance) of the package 200. This is possible because the metallization portion 204 and/or the integrated device 107 is/are offset (e.g., horizontally offset) from the integrated device 103 and does not cover the back side of the integrated device 103. In some implementations, the use of the plurality of wire bonds 108 help provide high aspect ratio interconnects that can extend through the encapsulation layer 106, and may be useful for the integrated device 103 with high thicknesses.

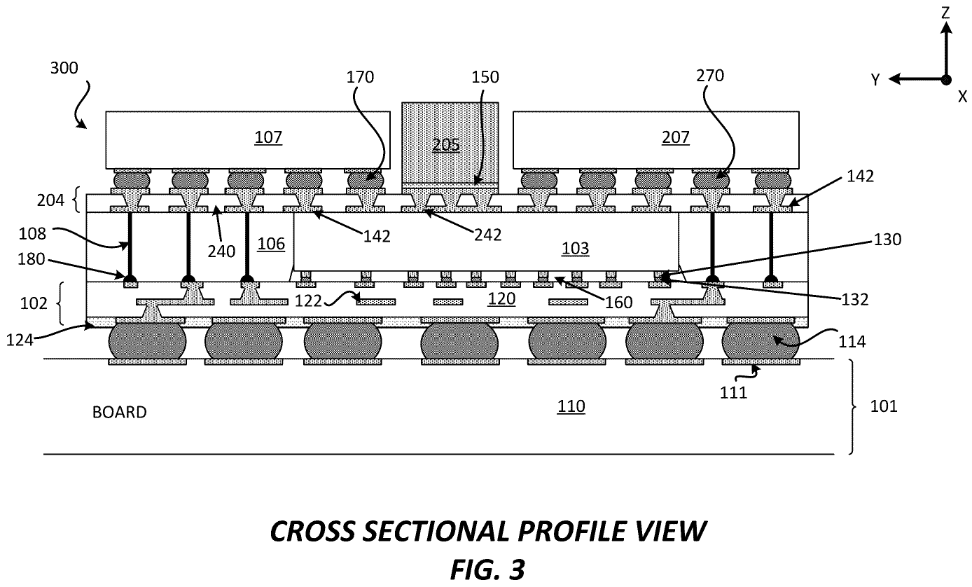

FIG. 3 illustrates a cross sectional profile view of a package 300 that includes a plurality of wire bonds. The package 300 is similar to the package 200 of FIG. 2, and may include similar components that are arranged in a similar manner. Thus, the description of the components in FIG. 2 may also be applicable to the various components of the package 300 of FIG. 3. The package 300 may be a package on package (PoP). The package 300 is coupled to a board 101 through a plurality of solder interconnects 114.

The package 300 includes a substrate 102, a metallization portion 204, an integrated device 103, an integrated device 107, an integrated device 207, a heat sink 205, a plurality of wire bonds 108 and an encapsulation layer 106. The integrated device 107 is coupled to the plurality of metallization interconnects 142 of the metallization portion 204 through a plurality of solder interconnects 170. The integrated device 207 is coupled to the plurality of metallization interconnects 142 of the metallization portion 204 through a plurality of solder interconnects 270. The heat sink 205 is coupled to the plurality of metallization interconnects 242 through a thermal interface material 150. The heat sink 205 is located laterally between the integrated device 107 and the integrated device 207.

The configuration of the package 300 provides a package with improved heat dissipation and/or thermal performance, which helps improve the performance (e.g., thermal performance) of the package 300. This is possible because the metallization portion 204 and/or the integrated device 107 is/are offset (e.g., horizontally offset) from the integrated device 103 and does not cover the back side of the integrated device 103. In some implementations, the use of the plurality of wire bonds 108 help provide high aspect ratio interconnects that can extend through the encapsulation layer 106, and may be useful for the integrated device 103 with high thicknesses.

An integrated device (e.g., 103) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 200, 300) may be implemented in a radio frequency (RF) package. The RF package may be a radio frequency front end (RFFE) package. A package (e.g., 100, 200, 300) may be configured to provide Wireless Fidelity (WiFi) communication and/or cellular communication (e.g., 2G, 3G, 4G, 5G, 6G). The packages (e.g., 100, 200, 300) may be configured to support Global System for Mobile (GSM) Communications, Universal Mobile Telecommunications System (UMTS), and/or Long-Term Evolution (LTE). The packages (e.g., 100, 200, 300) may be configured to transmit and receive signals having different frequencies and/or communication protocols.

### Exemplary Sequence for Fabricating a Package Comprising Wire Bonds

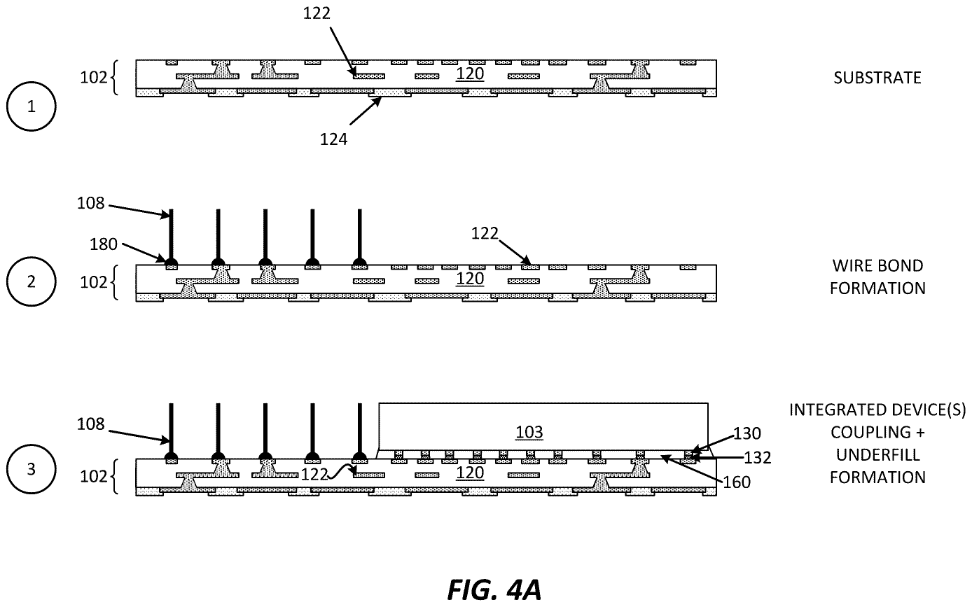

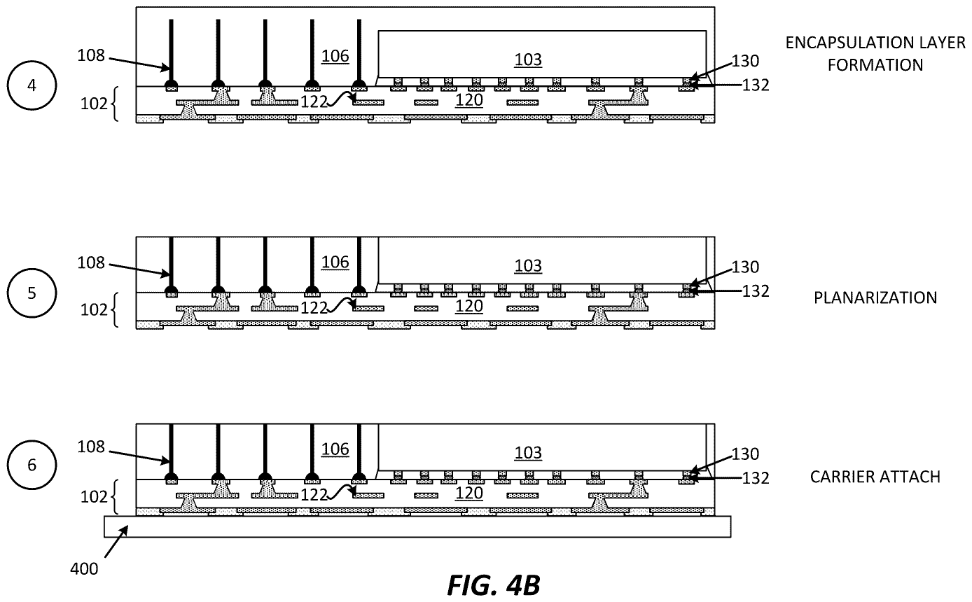

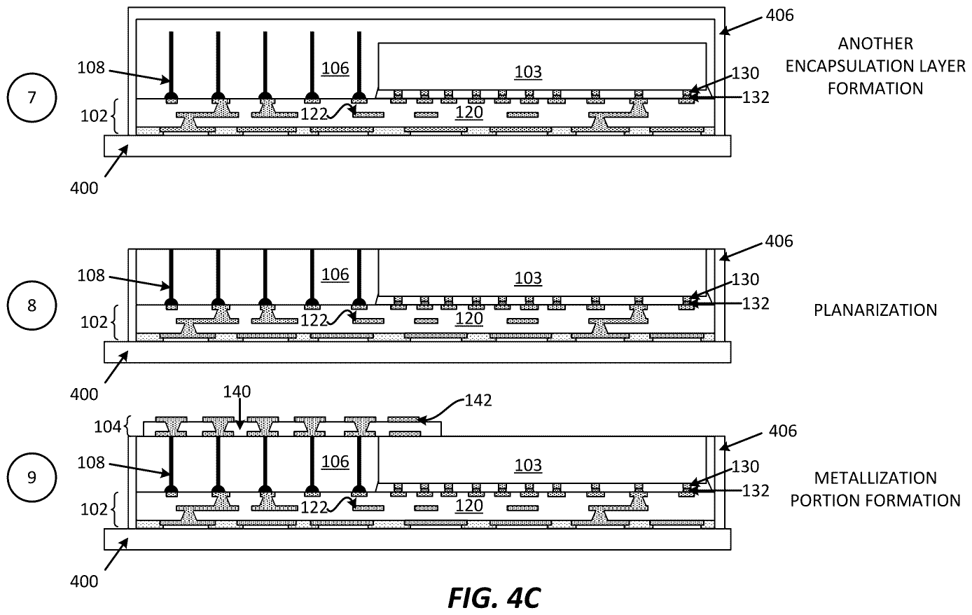

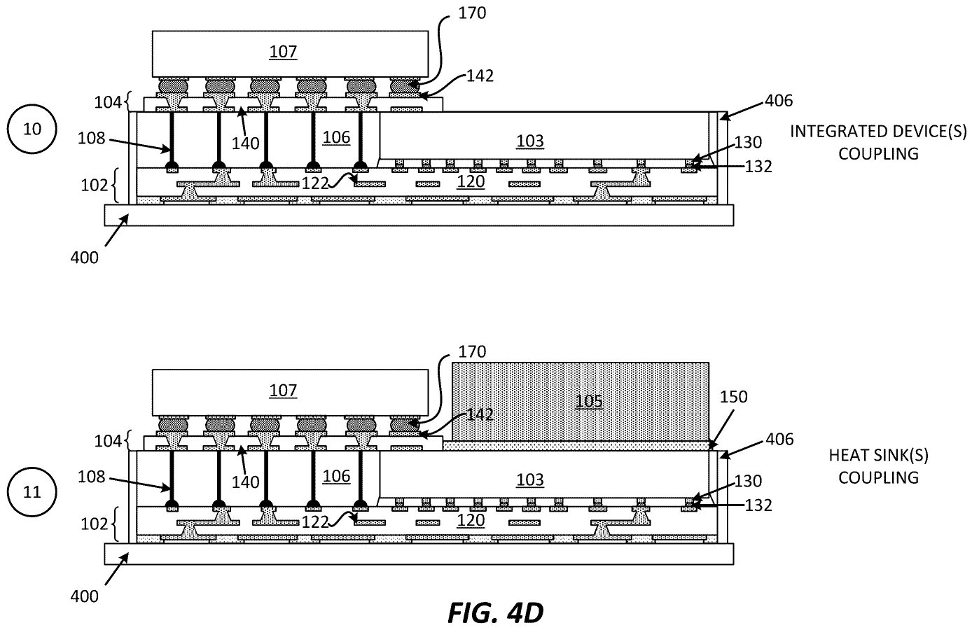

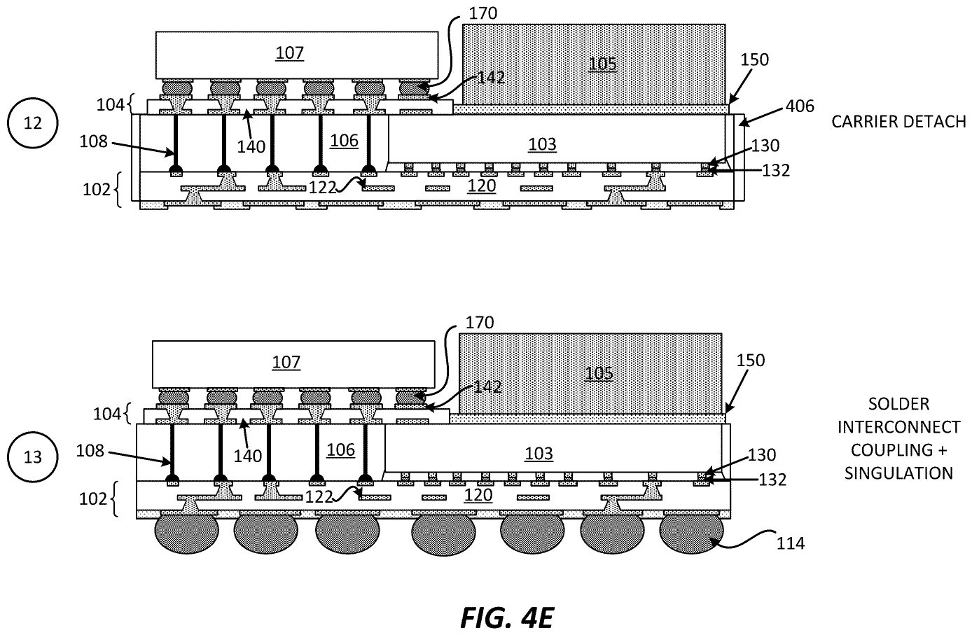

In some implementations, fabricating a package includes several processes. FIGS. 4A-4E illustrate an exemplary sequence for providing or fabricating a package. In some implementations, the sequence of FIGS. 4A-4E may be used to provide or fabricate the package 100. However, the process of FIGS. 4A-4E may be used to fabricate any of the packages described in the disclosure.

It should be noted that the sequence of FIGS. 4A-4E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 4A, illustrates a state after a substrate 102 is provided. Providing the substrate 102 may include fabricating the substrate 102. The substrate 102 may include at least one dielectric layer 120, a plurality of interconnects 122 and a solder resist layer 124. The substrate 102 may be a laminated substrate. The substrate 102 may include a coreless substrate or a cored substrate.

Stage 2 illustrates a state after a plurality of wire bonds 108 are formed and coupled to the substrate 102. The plurality of wire bonds 108 may include a plurality of ball bonds 180. A wire bonding process may be used to couple the plurality of wire bonds 108 to the substrate 102. The plurality of ball bonds 180 may be coupled to and touch the plurality of interconnects 122 of the substrate 102.

Stage 3 illustrates a state after an integrated device 103 is coupled to the substrate 102 through a plurality of pillar interconnects 130 and/or a plurality of solder interconnects 132. A solder reflow process may be used to couple the integrated device 103 to the substrate 102. The plurality of solder interconnects 132 may be coupled to and touch the plurality of interconnects 122 of the substrate 102. Stage 3 may also illustrates a state after an underfill 160 is provided and formed between the integrated device 103 and the substrate 102. The underfill 160 may at least partially surround the plurality of pillar interconnects 130 and/or the plurality of solder interconnects 132.

Stage 4, as shown in FIG. 4B, illustrates a state after an encapsulation layer 106 is provided and coupled to the substrate 102. The encapsulation layer 106 may at least partially encapsulate the integrated device 103 and the plurality of wire bonds 108. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded.

Stage 5 illustrates a state after a planarization process of the encapsulation layer 106. A portion of the encapsulation layer 106, a portion of the plurality of wire bonds 108 and/or a back side portion of the integrated device 103 may be removed and/or grinded off.

Stage 6 illustrates a state after a carrier 400 is attached to the substrate 102, or after the substrate 102 is coupled to the carrier 400. An adhesive may be used to couple the substrate 102 to the carrier 400.

Stage 7, as shown in FIG. 4C, illustrates a state after an encapsulation layer 406 is provided and coupled to the encapsulation layer 106. The encapsulation layer 406 may at least partially encapsulate the encapsulation layer 106. The encapsulation layer 406 may include a mold, a resin, an epoxy and/or a filler. The encapsulation layer 406 may be provided by using a compression and transfer molding process, a sheet molding process, or a liquid molding process. The encapsulation layer 406 may be over molded. The encapsulation layer 406 may be similar or the same as the encapsulation layer 106. In some implementations, the encapsulation layer 406 may be considered as a separate encapsulation layer from the encapsulation layer 106. In some implementations, the encapsulation layer 406 and the encapsulation layer 106 may be considered as the same encapsulation layer. In some implementations, the encapsulation layer 406 may be optional.

Stage 8 illustrates a state after a planarization process of the encapsulation layer 406. A portion of the encapsulation layer 406 and/or a portion of the encapsulation layer 106 may be removed and/or grinded off.

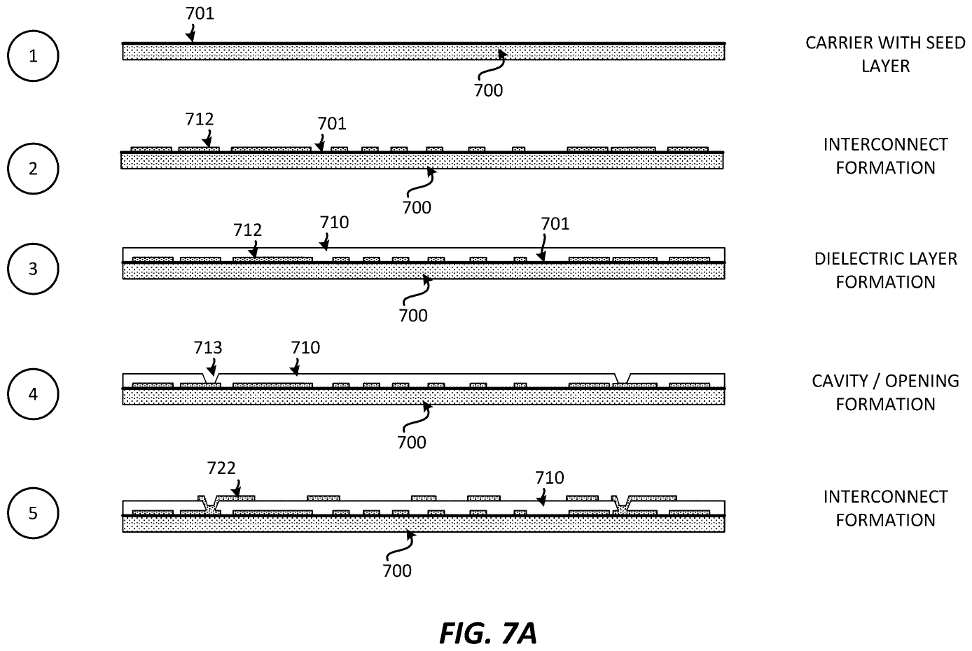

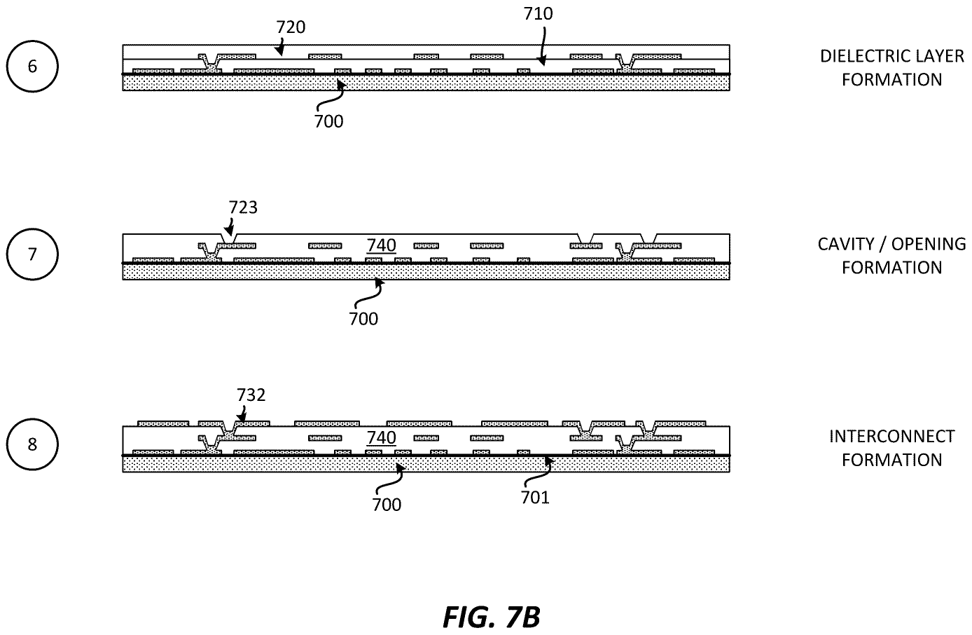

Stage 9 illustrates a state after a metallization portion 104 is formed and coupled to the integrated device 103, the encapsulation layer 106 and the plurality of wire bonds 108. The metallization portion 104 may include at least one dielectric layer 140 and a plurality of metallization interconnects 142. The metallization portion 104 may be formed and coupled to a back side of the integrated device 103. In some implementations, a deposition process, a lamination process, an etching process (e.g., photo etching process), a laser process, an exposure process, a development process, a lithography process, a plating process, and/or a strip process may be used to form the metallization portion 104. An example of forming a metallization portion is illustrated and described below in at least FIGS. 7A-7B.

Stage 10, as shown in FIG. 4D, illustrates a state after an integrated device 107 is coupled to the metallization portion 104 through a plurality of solder interconnects 170. A solder reflow process may be used to couple the integrated device 107 to the plurality of metallization interconnects 142 through the plurality of solder interconnects 170.

Stage 11 illustrates a state after a heat sink 105 is coupled to a back side of the integrated device 103 through a thermal interface material (TIM) 150. In some implementations, the thermal interface material (TIM) 150 is disposed on the back side of the integrated device 103, and then the heat sink 105 is placed and coupled to the thermal interface material (TIM) 150. In some implementations, the heat sink 105 may touch the back side of the integrated device 103.

Stage 12 of FIG. 4E, illustrates a state after the carrier 400 is detached from the substrate 102. In some implementations, the carrier 400 may be uncoupled from the substrate 102.

Stage 13 illustrates a state after a plurality of solder interconnects 114 are coupled to the substrate 102. A solder reflow process may be used to couple the plurality of solder interconnects 114 to the plurality of interconnects 122 of the substrate 102. Stage 13 may also illustrate a state after singulation. A mechanical process (e.g., saw process) may be used to perform singulation. Singulation may occur when the package is formed from wafers and/or panels, and singulated into individual packages.

### Exemplary Sequence for Fabricating a Package Comprising Wire Bonds

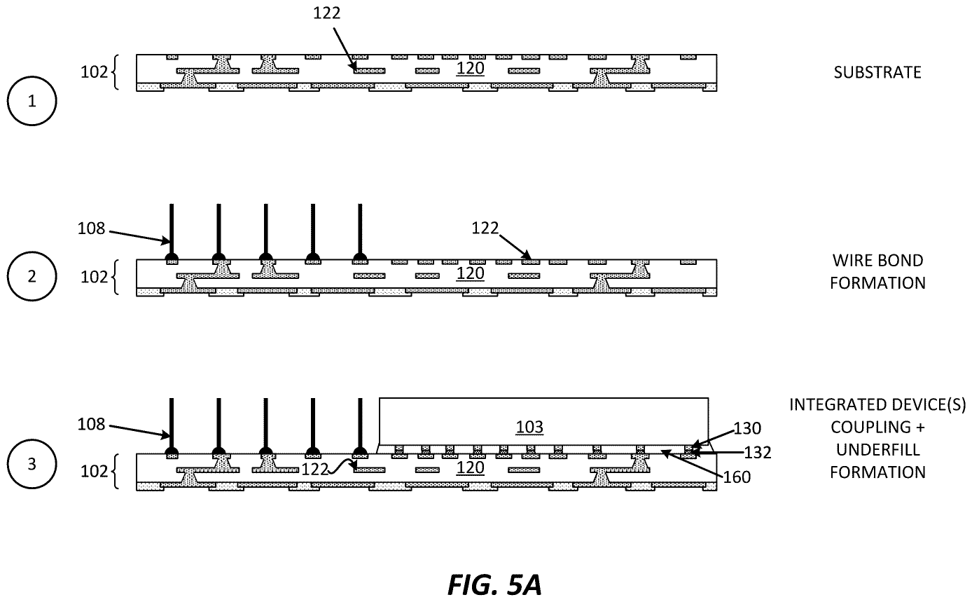

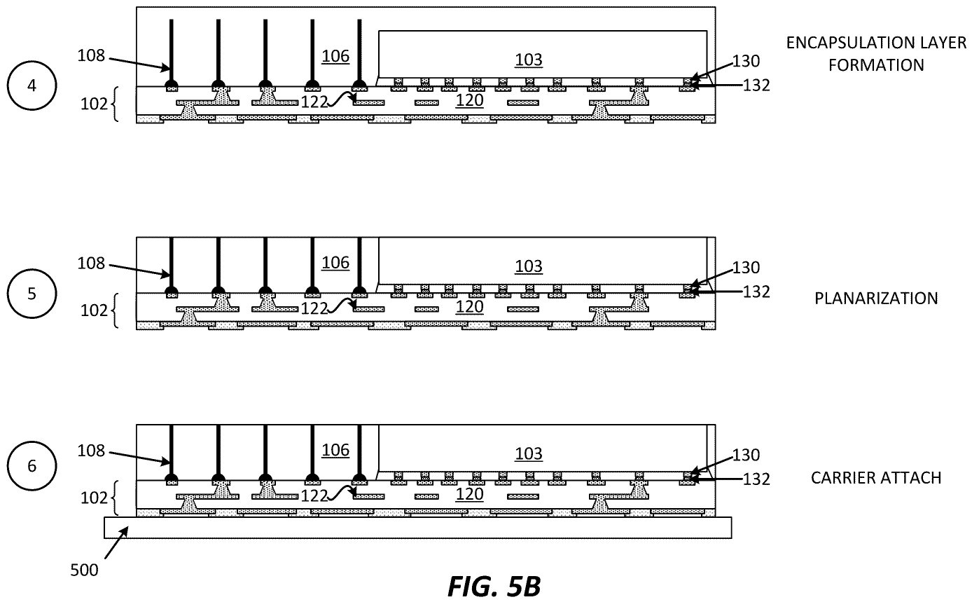

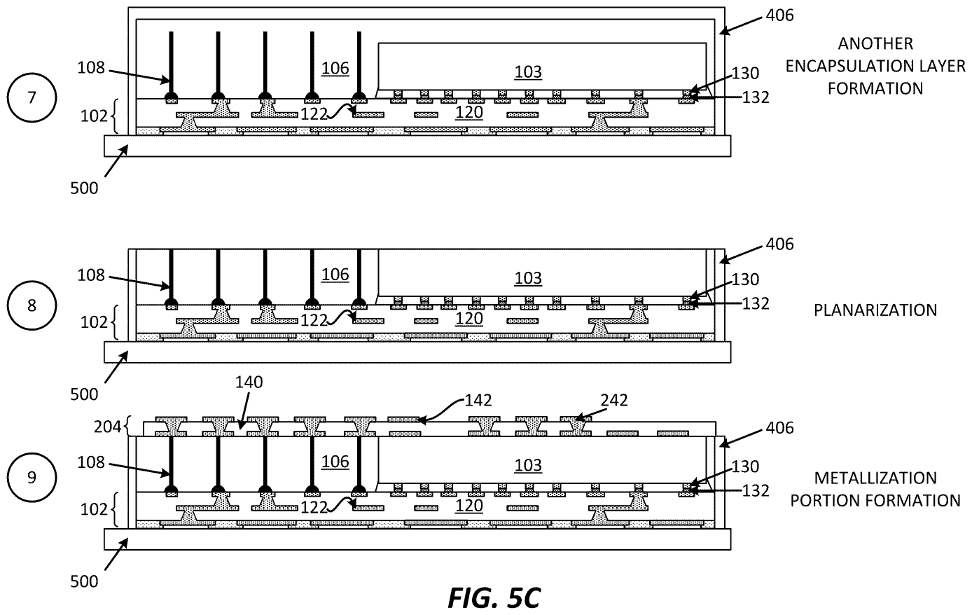

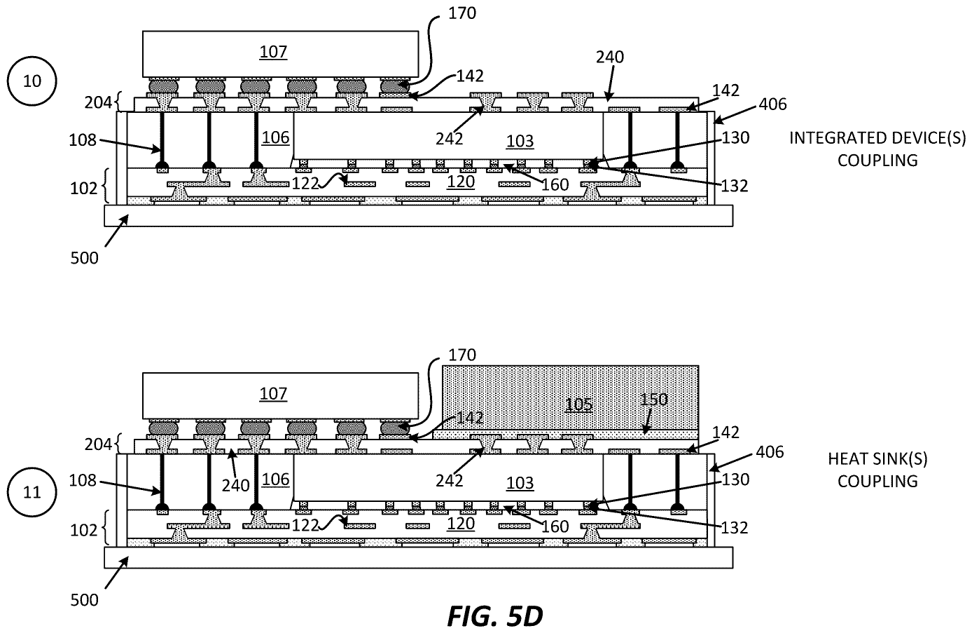

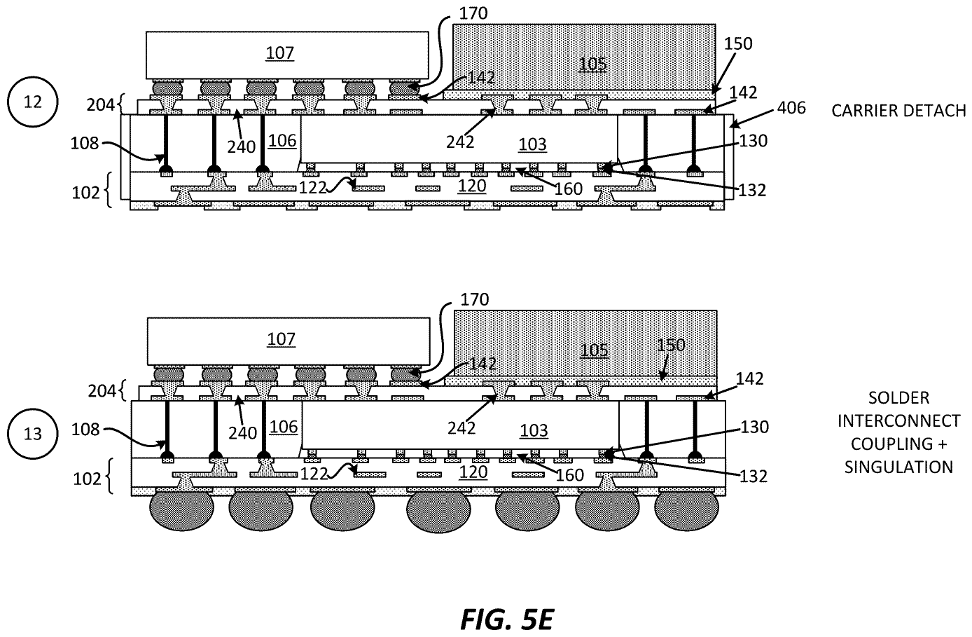

In some implementations, fabricating a package includes several processes. FIGS. 5A-5E illustrate an exemplary sequence for providing or fabricating a package. In some implementations, the sequence of FIGS. 5A-5E may be used to provide or fabricate the package 200. However, the process of FIGS. 5A-5E may be used to fabricate any of the packages described in the disclosure.

It should be noted that the sequence of FIGS. 5A-5E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 5A, illustrates a state after a substrate 102 is provided. Providing the substrate 102 may include fabricating the substrate 102. The substrate 102 may include at least one dielectric layer 120, a plurality of interconnects 122 and a solder resist layer 124. The substrate 102 may be a laminated substrate. The substrate 102 may include a coreless substrate or a cored substrate.

Stage 2 illustrates a state after a plurality of wire bonds 108 are formed and coupled to the substrate 102. The plurality of wire bonds 108 may include a plurality of ball bonds 180. A wire bonding process may be used to couple the plurality of wire bonds 108 to the substrate 102. The plurality of ball bonds 180 may be coupled to and touch the plurality of interconnects 122 of the substrate 102.

Stage 3 illustrates a state after an integrated device 103 is coupled to the substrate 102 through a plurality of pillar interconnects 130 and/or a plurality of solder interconnects 132. A solder reflow process may be used to couple the integrated device 103 to the substrate 102. The plurality of solder interconnects 132 may be coupled to and touch the plurality of interconnects 122 of the substrate 102. Stage 3 may also illustrates a state after an underfill 160 is provided and formed between the integrated device 103 and the substrate 102. The underfill 160 may at least partially surround the plurality of pillar interconnects 130 and/or the plurality of solder interconnects 132.

Stage 4, as shown in FIG. 5B, illustrates a state after an encapsulation layer 106 is provided and coupled to the substrate 102. The encapsulation layer 106 may at least partially encapsulate the integrated device 103 and the plurality of wire bonds 108. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded.

Stage 5 illustrates a state after a planarization process of the encapsulation layer 106. A portion of the encapsulation layer 106, a portion of the plurality of wire bonds 108 and/or a back side portion of the integrated device 103 may be removed and/or grinded off.

Stage 6 illustrates a state after a carrier 500 is attached to the substrate 102, or after the substrate 102 is coupled to the carrier 500. An adhesive may be used to couple the substrate 102 to the carrier 500.

Stage 7, as shown in FIG. 5C, illustrates a state after an encapsulation layer 406 is provided and coupled to the encapsulation layer 106. The encapsulation layer 406 may at least partially encapsulate the encapsulation layer 106. The encapsulation layer 406 may include a mold, a resin, an epoxy and/or a filler. The encapsulation layer 406 may be provided by using a compression and transfer molding process, a sheet molding process, or a liquid molding process. The encapsulation layer 406 may be over molded. The encapsulation layer 406 may be similar or the same as the encapsulation layer 106. In some implementations, the encapsulation layer 406 may be considered as a separate encapsulation layer from the encapsulation layer 106. In some implementations, the encapsulation layer 406 and the encapsulation layer 106 may be considered as the same encapsulation layer. In some implementations, the encapsulation layer 406 may be optional.

Stage 8 illustrates a state after a planarization process of the encapsulation layer 406. A portion of the encapsulation layer 406 and/or a portion of the encapsulation layer 106 may be removed and/or grinded off.

Stage 9 illustrates a state after a metallization portion 204 is formed and coupled to the integrated device 103, the encapsulation layer 106 and the plurality of wire bonds 108. The metallization portion 204 may include at least one dielectric layer 140, a plurality of metallization interconnects 142 and a plurality of metallization interconnects 242. The metallization portion 204 may be formed and coupled to a back side of the integrated device 103. In some implementations, a deposition process, a lamination process, an etching process (e.g., photo etching process), a laser process, an exposure process, a development process, a lithography process, a plating process, and/or a strip process may be used to form the metallization portion 204. An example of forming a metallization portion is illustrated and described below in at least FIGS. 7A-7B.

Stage 10, as shown in FIG. 5D, illustrates a state after an integrated device 107 is coupled to the metallization portion 204 through a plurality of solder interconnects 170. A solder reflow process may be used to couple the integrated device 107 to the plurality of metallization interconnects 142 through the plurality of solder interconnects 170.

Stage 11 illustrates a state after a heat sink 105 is coupled to the metallization portion 204 through a thermal interface material (TIM) 150. In some implementations, the thermal interface material (TIM) 150 is disposed on the metallization portion 204, and then the heat sink 105 is placed and coupled to the thermal interface material (TIM) 150. In some implementations, the heat sink 105 may touch the metallization portion 204. For example, the heat sink 105 may touch the plurality of metallization interconnects 242 of the metallization portion 204.

Stage 12 of FIG. 5E, illustrates a state after the carrier 500 is detached from the substrate 102. In some implementations, the carrier 500 may be uncoupled from the substrate 102.

Stage 13 illustrates a state after a plurality of solder interconnects 114 are coupled to the substrate 102. A solder reflow process may be used to couple the plurality of solder interconnects 114 to the plurality of interconnects 122 of the substrate 102. Stage 13 may also illustrate a state after singulation. A mechanical process (e.g., saw process) may be used to perform singulation. Singulation may occur when the package is formed from wafers and/or panels, and singulated into individual packages.

### Exemplary Flow Diagram of a Method for Fabricating a Package Comprising Wire Bonds

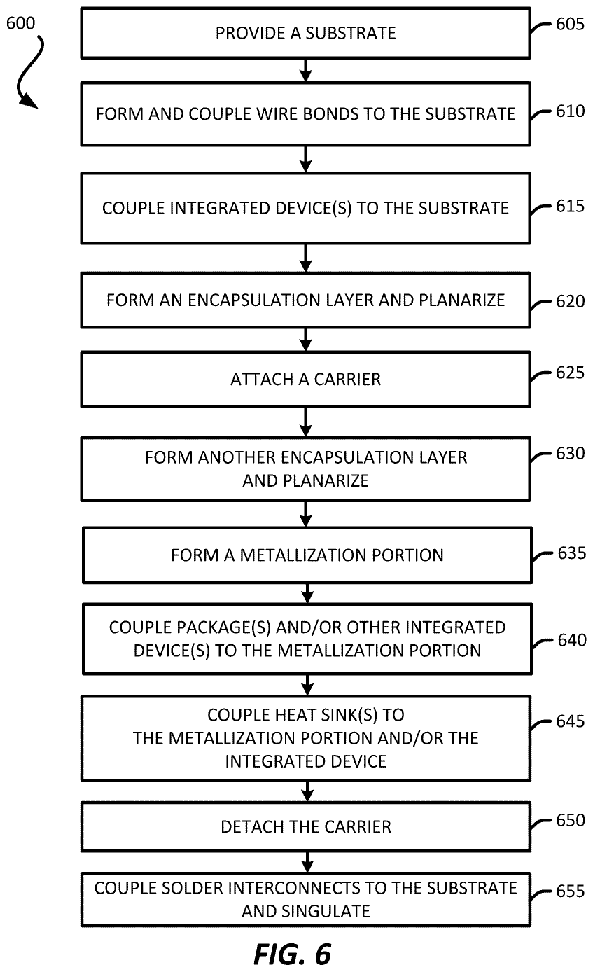

In some implementations, fabricating a package includes several processes. FIG. 6 illustrates an exemplary flow diagram of a method 600 for providing or fabricating a package. In some implementations, the method 600 of FIG. 6 may be used to provide or fabricate the package 100, the package 200, and/or the package 300 described in the disclosure. However, the method 600 may be used to provide or fabricate any of the packages described in the disclosure.

It should be noted that the method 600 of FIG. 6 may combine one or more processes in order to simplify and/or clarify the method for providing or fabricating a package. In some implementations, the order of the processes may be changed or modified.

The method provides (at 605) a substrate. Stage 1 of FIG. 4A, illustrates and describes an example of a state after a substrate 102 is provided. Providing the substrate 102 may include fabricating the substrate 102. The substrate 102 may include at least one dielectric layer 120, a plurality of interconnects 122 and a solder resist layer 124. The substrate 102 may be a laminated substrate. The substrate 102 may include a coreless substrate or a cored substrate.

The method forms and couples (at 610) a plurality of wire bonds to the substrate. Stage 2 of FIG. 4A, illustrates and describes an example of a state after a plurality of wire bonds 108 are formed and coupled to the substrate 102. The plurality of wire bonds 108 may include a plurality of ball bonds 180. A wire bonding process may be used to couple the plurality of wire bonds 108 to the substrate 102. The plurality of ball bonds 180 may be coupled to and touch the plurality of interconnects 122 of the substrate 102.

The method couples (at 615) at least one integrated device to the substrate. Stage 3 of FIG. 4A, illustrates and describes an example of a state after an integrated device 103 is coupled to the substrate 102 through a plurality of pillar interconnects 130 and/or a plurality of solder interconnects 132. A solder reflow process may be used to couple the integrated device 103 to the substrate 102. The plurality of solder interconnects 132 may be coupled to and touch the plurality of interconnects 122 of the substrate 102. Stage 3 may also illustrates a state after an underfill 160 is provided and formed between the integrated device 103 and the substrate 102. The underfill 160 may at least partially surround the plurality of pillar interconnects 130 and/or the plurality of solder interconnects 132.

The method forms (at 620) an encapsulation layer and planarizes the encapsulation layer. Stage 4 of FIG. 4B, illustrates and describes an example of a state after an encapsulation layer 106 is provided and coupled to the substrate 102. The encapsulation layer 106 may at least partially encapsulate the integrated device 103 and the plurality of wire bonds 108. The encapsulation layer 106 may include a mold, a resin, an epoxy and/or a filler. The encapsulation layer 106 may be provided by using a compression and transfer molding process, a sheet molding process, or a liquid molding process. The encapsulation layer 106 may be over molded.

Stage 5 of FIG. 4B, illustrates and describes an example of a state after planarization process of the encapsulation layer 106. A portion of the encapsulation layer 106, a portion of the plurality of wire bonds 108 and/or a back side portion of the integrated device 103 may be removed and/or grinded off.

The method attaches (at 625) a carrier to the substrate. Stage 6 of FIG. 4B, illustrates and describes an example of a state after a carrier 400 is attached to the substrate 102, or after the substrate 102 is coupled to the carrier 400. An adhesive may be used to couple the substrate 102 to the carrier 400.

The method forms (at 630) another encapsulation layer and planarizes the another encapsulation layer. Stage 7 of FIG. 4C, illustrates and describes an example of a state after an encapsulation layer 406 is provided and coupled to the encapsulation layer 106. The encapsulation layer 406 may at least partially encapsulate the encapsulation layer 106. The encapsulation layer 406 may include a mold, a resin, an epoxy and/or a filler. The encapsulation layer 406 may be provided by using a compression and transfer molding process, a sheet molding process, or a liquid molding process. The encapsulation layer 406 may be over molded. The encapsulation layer 406 may be similar or the same as the encapsulation layer 106. In some implementations, the encapsulation layer 406 may be considered as a separate encapsulation layer from the encapsulation layer 106. In some implementations, the encapsulation layer 406 and the encapsulation layer 106 may be considered as the same encapsulation layer. The encapsulation layer 406 may be optional.

Stage 8 of FIG. 4C, illustrates and describes an example of a state after a planarization process of the encapsulation layer 406. A portion of the encapsulation layer 406 and/or a portion of the encapsulation layer 106 may be removed and/or grinded off.

The method forms (at 635) a metallization portion. Stage 9 of FIG. 4C, illustrates and describes an example of a state after a metallization portion 104 is formed and coupled to the integrated device 103, the encapsulation layer 106 and the plurality of wire bonds 108. The metallization portion 104 may include at least one dielectric layer 140 and a plurality of metallization interconnects 142. The metallization portion 104 may be formed and coupled to a back side of the integrated device 103. In some implementations, a deposition process, a lamination process, an etching process (e.g., photo etching process), a laser process, an exposure process, a development process, a lithography process, a plating process, and/or a strip process may be used to form the metallization portion 104. An example of forming a metallization portion is illustrated and described below in at least FIGS. 7A-7B.

The method couples (at 640) at least one integrated device and/or at least one package to the metallization portion. Stage 10 of FIG. 4D, illustrates and describes an example of a state after an integrated device 107 is coupled to the metallization portion 104 through a plurality of solder interconnects 170. A solder reflow process may be used to couple the integrated device 107 to the plurality of metallization interconnects 142.

The method couples (at 645) at least one heat sink to the metallization portion and/or the back side of the integrated device. Stage 11 of FIG. 4D, illustrates and describes an example of a state after a heat sink 105 is coupled to a back side of the integrated device 103 through a thermal interface material (TIM) 150. In some implementations, the thermal interface material (TIM) 150 is disposed on the back side of the integrated device 103, and then the heat sink 105 is placed and coupled to the thermal interface material (TIM) 150. In some implementations, the heat sink 105 may touch the back side of the integrated device 103.

Stage 11 of FIG. 5D, illustrates and describes an example of a state after a heat sink 105 is coupled to the metallization portion 204 through a thermal interface material (TIM) 150. In some implementations, the thermal interface material (TIM) 150 is disposed on the metallization portion 204, and then the heat sink 105 is placed and coupled to the thermal interface material (TIM) 150. In some implementations, the heat sink 105 may touch the metallization portion 204.

The method detaches (at 650) the carrier from the substrate. Stage 12 of FIG. 4E, illustrates and describes an example of a state after the carrier 400 is detached from the substrate 102. In some implementations, the carrier 400 may be uncoupled from the substrate 102.

The method couples (at 655) a plurality of solder interconnects to the substrate and singulates. Stage 13 of FIG. 4E, illustrates and describes an example of a state after a plurality of solder interconnects 114 are coupled to the substrate 102. A solder reflow process may be used to couple the plurality of solder interconnects 114 to the plurality of interconnects 122 of the substrate 102. Stage 13 may also illustrate a state after singulation. A mechanical process (e.g., saw process) may be used to perform singulation. Singulation may occur when the package is formed from wafers and/or panels, and singulated into individual packages.

### Exemplary Sequence for Fabricating a Metallization Portion

In some implementations, fabricating a metallization portion includes several processes. FIGS. 7A-7B illustrate an exemplary sequence for providing or fabricating a metallization portion. In some implementations, the sequence of FIGS. 7A-7B may be used to provide or fabricate the metallization portion 104 and/or the metallization portion 204. However, the process of FIGS. 7A-7B may be used to fabricate any metallization portion including any of the metallization portions described in the disclosure.

It should be noted that the sequence of FIGS. 7A-7B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 7A, illustrates a state after a carrier 700 is provided. A seed layer 701 may be located over the carrier 700. The carrier 700 may be replaced with other components and/or materials.

Stage 2 illustrates a state after a plurality of interconnects 712 are formed. The interconnects 712 may be located over the seed layer 701. A lithography process, a plating process, a strip process and/or an etching process may be used to form the plurality of interconnects 712. The interconnects 712 may represent at least some of the metallization interconnects from the plurality of metallization interconnects 142.

Stage 3 illustrates a state after a dielectric layer 710 is formed over the carrier 700, the seed layer 701 and the plurality of interconnects 712. A deposition and/or lamination process may be used to form the dielectric layer 710. The dielectric layer 710 may include prepreg and/or polyimide. The dielectric layer 710 may include a photo-imageable dielectric. However, different implementations may use different materials for the dielectric layer.

Stage 4 illustrates a state after a plurality of cavities 713 is formed in the dielectric layer 710. The plurality of cavities 713 may be formed using an etching process (e.g., photo etching process), a laser process, an exposure process and/or a development process.

Stage 5 illustrates a state after interconnects 722 are formed in and over the dielectric layer 710, including in and over the plurality of cavities 713. For example, a via, pad and/or traces may be formed. A lithography process, a plating process, a strip process and/or an etching process may be used to form the interconnects.

Stage 6, as shown in FIG. 7B, illustrates a state after a dielectric layer 720 is formed over the dielectric layer 710 and the plurality of interconnects 722. A deposition and/or lamination process may be used to form the dielectric layer 720. The dielectric layer 720 may include prepreg and/or polyimide. The dielectric layer 720 may include a photo-imageable dielectric. However, different implementations may use different materials for the dielectric layer.

Stage 7, illustrates a state after a plurality of cavities 723 is formed in the dielectric layer 740. The dielectric layer 740 may represent the dielectric layer 710 and/or the dielectric layer 720. The plurality of cavities 723 may be formed using an etching process (e.g., photo etching process), a laser process, an exposure process and/or a development process.

Stage 8 illustrates a state after interconnects 732 are formed in and over the dielectric layer 740, including in and over the plurality of cavities 723. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

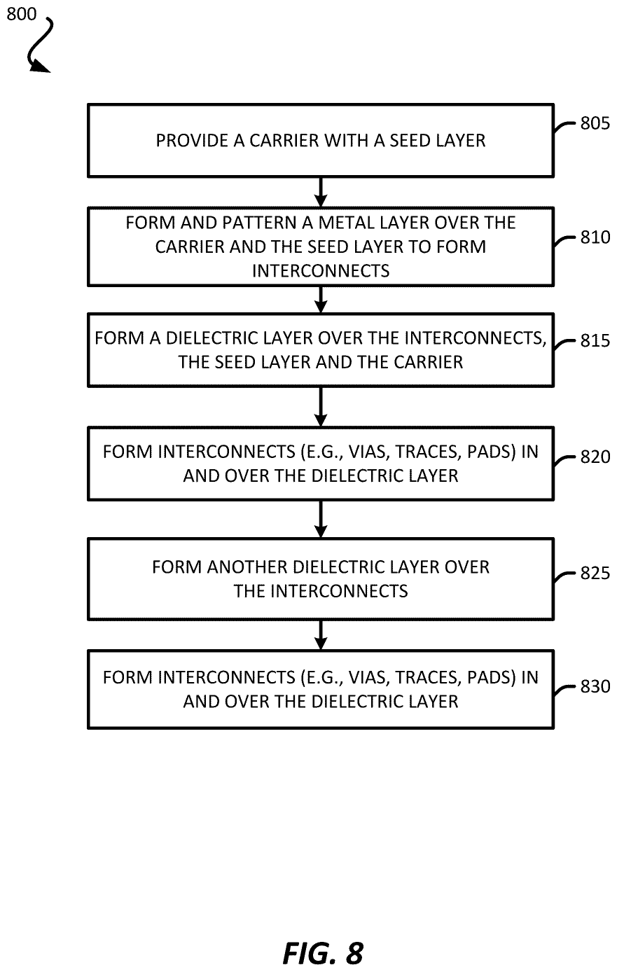

In some implementations, fabricating a metallization portion includes several processes. FIG. 8 illustrates an exemplary flow diagram of a method 800 for providing or fabricating a metallization portion. In some implementations, the method 800 of FIG. 8 may be used to provide or fabricate the metallization portion(s) of the disclosure. For example, the method 800 of FIG. 8 may be used to fabricate the metallization portion 104 and/or the metallization portion 204.

It should be noted that the method 800 of FIG. 8 may combine one or more processes in order to simplify and/or clarify the method for providing or fabricating a metallization portion. In some implementations, the order of the processes may be changed or modified.

The method provides (at 805) a carrier with a seed layer. Stage 1 of FIG. 7A, illustrates and describes an example of a state after a carrier 700 is provided. A seed layer 701 may be located over the carrier 700. The carrier 700 may be replaced with other components and/or materials.

The method forms and patterns (at 810) a plurality of interconnects. Stage 2 of FIG. 7A, illustrates and describes an example of a state after a plurality of interconnects 712 are formed. The interconnects 712 may be located over the seed layer 701. A lithography process, a plating process, a strip process and/or an etching process may be used to form the plurality of interconnects 712. The interconnects 712 may represent at least some of the metallization interconnects from the plurality of metallization interconnects 142.

The method forms (at 810) a dielectric layer. Stage 3 of FIG. 7A, illustrates and describes an example of a state after a dielectric layer 710 is formed over the carrier 700, the seed layer 701 and the plurality of interconnects 712. A deposition and/or lamination process may be used to form the dielectric layer 710. The dielectric layer 710 may include prepreg and/or polyimide. The dielectric layer 710 may include a photo-imageable dielectric. However, different implementations may use different materials for the dielectric layer.

The method forms (at 820) a plurality of interconnects. Forming a plurality of interconnects may including forming a plurality of cavities in a dielectric layer and a performing a plating process. Stage 4 of FIG. 7A, illustrates and describes an example of a state after a plurality of cavities 713 is formed in the dielectric layer 710. The plurality of cavities 713 may be formed using an etching process (e.g., photo etching process), a laser process, an exposure process and/or a development process.

Stage 5 of FIG. 7A, illustrates and describes an example of a state after interconnects 722 are formed in and over the dielectric layer 710, including in and over the plurality of cavities 713. For example, a via, pad and/or traces may be formed. A lithography process, a plating process, a strip process and/or an etching process may be used to form the interconnects.

The method forms (at 825) another dielectric layer. Stage 6 of FIG. 7B, illustrates and describes an example of a state after a dielectric layer 720 is formed over the dielectric layer 710 and the plurality of interconnects 722. A deposition and/or lamination process may be used to form the dielectric layer 720. The dielectric layer 720 may include prepreg and/or polyimide. The dielectric layer 720 may include a photo-imageable dielectric. However, different implementations may use different materials for the dielectric layer.

The method forms (at 830) a plurality of interconnects. Forming a plurality of interconnects may including forming a plurality of cavities in a dielectric layer and a performing a plating process. Stage 7 of FIG. 7B, illustrates and describes an example of a state after a plurality of cavities 723 is formed in the dielectric layer 740. The dielectric layer 740 may represent the dielectric layer 710 and/or the dielectric layer 720. The plurality of cavities 723 may be formed using an etching process (e.g., photo etching process), a laser process, an exposure process and/or a development process.

Stage 8 of FIG. 7B, illustrates and describes an example of a state after interconnects 732 are formed in and over the dielectric layer 740, including in and over the plurality of cavities 723. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

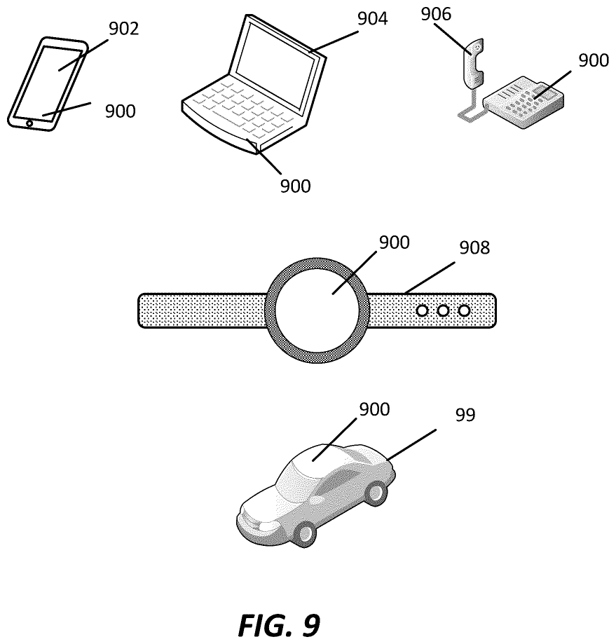

FIG. 9 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 902, a laptop computer device 904, a fixed location terminal device 906, a wearable device 908, or automotive vehicle 910 may include a device 900 as described herein. The device 900 may be, for example, any of the devices and/or integrated circuit (IC) packages described herein. The devices 902, 904, 906 and 908 and the vehicle 910 illustrated in FIG. 9 are merely exemplary. Other electronic devices may also feature the device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-3, 4A-4E, 5A-5E, 6, 7A-7B, and 8-9 may be rearranged and/or combined into a single component, process, feature or function or embodied in several components, processes, or functions. Additional elements, components, processes, and/or functions may also be added without departing from the disclosure. It should also be noted FIGS. 1-3, 4A-4E, 5A-5E, 6, 7A-7B, and 8-9 and its corresponding description in the present disclosure is not limited to dies and/or ICs. In some implementations, FIGS. 1-3, 4A-4E, 5A-5E, 6, 7A-7B, and 8-9 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a substrate; an integrated device coupled to the substrate; a metallization portion coupled to a back side of the integrated device; a plurality of wire bonds coupled to the substrate and the metallization portion; and an encapsulation layer coupled to the metallization portion and the substrate, wherein the encapsulation layer at least partially encapsulates the integrated device and the plurality of wire bonds.

Aspect 2: The package of aspect 1, wherein the substrate comprises at least one substrate dielectric layer and a plurality of interconnects, and wherein the metallization portion comprises at least one dielectric layer and a plurality of metallization interconnects.

Aspect 3: The package of aspect 2, wherein the plurality of wire bonds are coupled to the plurality of interconnects and the plurality of metallization interconnects.

Aspect 4: The package of aspect 3, wherein the plurality of wire bonds comprise a plurality of ball bonds, and wherein the plurality of ball bonds are coupled to and touching the plurality of interconnects of the substrate.

Aspect 5: The package of aspects 1 through 4, further comprising another integrated device or another package, coupled to the metallization portion through a plurality of solder interconnects.

Aspect 6: The package of aspects 1 through 5, wherein the metallization portion is coupled to and touching the back side of the integrated device.

Aspect 7: The package of aspects 1 through 6, wherein the metallization portion comprises a plurality of heat sink interconnects configured as a heat sink.

Aspect 8: The package of aspects 1 through 7, further comprising a heat sink.

Aspect 9: The package of aspect 8, wherein the heat sink is coupled to the metallization portion through a thermal interface material (TIM) and/or an adhesive.

Aspect 10: The package of aspect 8, wherein the heat sink is coupled to the back side of the integrated device through a thermal interface material (TIM) and/or an adhesive.

Aspect 11: The package of aspects 1 through 10, wherein the metallization portion includes a redistribution portion.

Aspect 12: The package of aspect 11, wherein the redistribution portion includes a plurality of redistribution interconnects.

Aspect 13: The package of aspects 1 through 12, wherein the integrated device is coupled to the substrate through a plurality of pillar interconnects and a plurality of solder interconnects.

Aspect 14: The package of aspect 13, further comprising an underfill located between the integrated device and the substrate.

Aspect 15: The package of aspect 14, wherein the underfill includes a different material from the encapsulation layer.

Aspect 16: The package of aspects 1 through 15, further comprising a second integrated device coupled to the metallization portion, and a third integrated device coupled to the metallization portion.

Aspect 17: The package of aspect 16, further comprising a heat sink coupled to the metallization portion, wherein the heat sink is located laterally between the second integrated device and the third integrated device.

Aspect 18: The package of aspects 1 through 17, wherein the substrate includes a laminated substrate.

Aspect 19: The package of aspects 1 through 18, further comprising a second encapsulation layer that at least partially encapsulate the encapsulation layer.

Aspect 20: The package of aspects 1 through 19, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 21: A method for fabricating a package. The method provides a substrate. The method forms and couple a plurality of wire bonds to the substrate. The method couples an integrated device to the substrate. The method forms an encapsulation layer that is coupled to the substrate, the integrated device and the plurality of wire bonds. The method forms a metallization portion that is coupled to the encapsulation layer and the plurality of wire bonds.

Aspect 22: The method of aspect 21, wherein the substrate comprises at least one substrate dielectric layer and a plurality of interconnects, and wherein the metallization portion comprises at least one dielectric layer and a plurality of metallization interconnects.

Aspect 23: The method of aspect 22, wherein the plurality of wire bonds are coupled to the plurality of interconnects and the plurality of metallization interconnects.

Aspect 24: The method of aspect 23, wherein the plurality of wire bonds comprise a plurality of ball bonds, and wherein the plurality of ball bonds are coupled to and touching the plurality of interconnects of the substrate.

Aspect 25: The method of aspects 21 through 24, further comprising coupling another integrated device or another package, to the metallization portion through a plurality of solder interconnects.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate;
an integrated device coupled to the substrate;
a metallization portion coupled to a back side of the integrated device;
a plurality of wire bonds coupled to the substrate and the metallization portion; and
an encapsulation layer coupled to the metallization portion and the substrate, wherein the encapsulation layer at least partially encapsulates the integrated device and the plurality of wire bonds.

2. The package of claim 1,
wherein the substrate comprises at least one substrate dielectric layer and a plurality of interconnects, and
wherein the metallization portion comprises at least one dielectric layer and a plurality of metallization interconnects.

3. The package of claim 2, wherein the plurality of wire bonds are coupled to the plurality of interconnects and the plurality of metallization interconnects.

4. The package of claim 3,
wherein the plurality of wire bonds comprise a plurality of ball bonds, and
wherein the plurality of ball bonds are coupled to and touching the plurality of interconnects of the substrate.

5. The package of claim 1, further comprising another integrated device or another package, coupled to the metallization portion through a plurality of solder interconnects.

6. The package of claim 1, wherein the metallization portion is coupled to and touching the back side of the integrated device.

7. The package of claim 1, wherein the metallization portion comprises a plurality of heat sink interconnects configured as a heat sink.

8. The package of claim 1, further comprising a heat sink.

9. The package of claim 8, wherein the heat sink is coupled to the metallization portion through a thermal interface material (TIM) and/or an adhesive.

10. The package of claim 8, wherein the heat sink is coupled to the back side of the integrated device through a thermal interface material (TIM) and/or an adhesive.

11. The package of claim 1, wherein the metallization portion includes a redistribution portion.

12. The package of claim 11, wherein the redistribution portion includes a plurality of redistribution interconnects.

13. The package of claim 1, wherein the integrated device is coupled to the substrate through a plurality of pillar interconnects and a plurality of solder interconnects.

14. The package of claim 13, further comprising an underfill located between the integrated device and the substrate.

15. The package of claim 14, wherein the underfill includes a different material from the encapsulation layer.

16. The package of claim 1, further comprising:
a second integrated device coupled to the metallization portion, and
a third integrated device coupled to the metallization portion.

17. The package of claim 16, further comprising a heat sink coupled to the metallization portion, wherein the heat sink is located laterally between the second integrated device and the third integrated device.

18. The package of claim 1, wherein the substrate includes a laminated substrate.

19. The package of claim 1, further comprising a second encapsulation layer that at least partially encapsulate the encapsulation layer.

20. The package of claim 1, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
